(19) United States
(12) Patent Application Publication
(10) Pub. No.: US 2003/0030075 A1
(43) Pub. Date: Feb. 13, 2003

(54) Semiconductor device and method of arranging transistors for forming TEG

(75) Inventors: Kenji Yamaguchi, Tokyo (JP); Hiroyuki Amishiro, Tokyo (JP); Motoshige Igarashi, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 10/113,294

(22) Filed: Apr. 2, 2002

(30) Foreign Application Priority Data
Aug. 8, 2001 (JP) 2001-240640

(51) Int. Cl. H01L 27/10; H01L 21/82

(52) U.S. Cl. 257/206; 257/203; 257/208; 438/128; 438/129; 438/309

(57) ABSTRACT

MOS transistors (TR1, TR2) are arranged closer to a pad (SP) in descending order of current-driving capability. Namely, the MOS transistors (TR1, TR2) are arranged from closer part to the pad (SP) in descending order of value of W/L obtained by dividing a gate width (W) of a gate electrode by a gate length (L) of the same. When a transistor has a large current-driving capability, the value of source-to-drain current is high. For this reason, the MOS transistors are arranged from closer part to the pad for source electrode in descending order of current-driving capability, to thereby reduce the amount of voltage drop in an interconnect line. A current value of the transistor becomes lower as a distance between the pad and the transistor increases. As a result, it is allowed to reduce influence on the transistor characteristics exerted by voltage drop due to interconnection resistance.

### BACKGROUND OF THE INVENTION

1. Field of the Invention

The present invention relates to a semiconductor device holding TEG (test element group) mounted thereon including a device such as transistor and a method of arranging transistors for forming TEG.

2. Description of the Background Art

The development of a semiconductor device such as a ULSI circuit requires as an important issue precise evaluation of variation in characteristic of a device and of a circuit resulting from fluctuation in various parameters in manufacturing processes. In a wafer processing for forming a device and a circuit into a wafer, a device and a circuit constituting a so-called TEG for monitoring characteristics are generally formed in the wafer. By measuring characteristics of TEG, variation in characteristic of the device and circuit to be employed as products is evaluated.

As illustrated in FIG. 14, TEG's are currently arranged in line in regions AR defined on dicing lines DL for cutting the wafer into product chips. This is because the product chips should cover the largest possible area in the wafer. In the present specification and claims, such TEG's are referred to as in-line TEG's.

FIG. 15 is a view exemplifying the structure of TEG for forming in-line TEG's. The TEG illustrated in FIG. 15 includes MOS (metal oxide semiconductor) transistors TR1 and TR2 each serving as a device. Also illustrated in FIG. 15 are pads SP, DP1, DP2, GP and BP for respectively supplying potential to source electrodes SE1, SE2 of the transistors TR1, TR2, to a drain electrode DE1 of the transistor TR1, to a drain electrode DE2 of the transistor TR2, to gate electrodes GE1, GE2 of the transistors TR1, TR2 and to body electrodes BE1, BE2 of the transistors TR1, TR2. The pad SP for source electrode, the pad GP for gate electrode and the pad BP for body electrode are shared between the MOS transistors TR1 and TR2. In contrast, the pads DP1 and DP2 for drain electrode are provided for the respective MOS transistors.

In order to keep the largest possible area of the product chips, the dicing line DL is generally given a width as small as the width of one pad according to arrangement of such in-line TEG's. For this reason, interconnect lines SL, GL, BL, DL1 and DL2 for establishing connection between each pad and electrode are each designed to have a small width.

The trend toward finer structure brings problems to the in-line TEG's in the background art illustrated in FIG. 15 as follows.

(1) Distances from the MOS transistors TR1 and TR2 to the pad SP for source electrode are different from each other. Therefore, one MOS transistor more distanced from the pad SP than the other is more seriously affected by voltage drop caused by resistance in the interconnect line SL. Due to this, the characteristics of this transistor cannot be evaluated with precision. Further, the interconnect line SL is elongated and routed avoiding the region for the pad on the dicing line DL, thereby causing interconnection resistance that contributes to the increase in voltage drop.

FIG. 16 is a sectional view of the MOS transistor for schematically illustrating parasitic resistance in each interconnect line and each part. As illustrated in FIG. 16, when an interconnection resistance Rm is added to the source side (S), the characteristics of the MOS transistor are affected.

FIGS. 17 and 18 are graphs showing the characteristics of the transistor affected by the interconnection resistance Rm added thereto. FIG. 17 shows characteristics obtained from the relation expressed as “drain-to-source current—gate-to-source voltage”. FIG. 18 shows characteristics obtained from the relation expressed as “drain-to-source current—drain-to-source voltage”. As can be seen from the graphs in both figures, the MOS transistor having the interconnection resistance Rm (Rm is set to be 5Ω, for example) results in the reduction in the drain-to-source current as compared with the MOS transistor having no interconnection resistance (namely, Rm=0).

(2) Accompanied by the trend toward smaller thickness of a gate insulating film, the necessity has arisen for precisely evaluating capacitance between a gate electrode and an active region and leakage current flowing therebetween. Due to the fact that the area of the gate electrode and the region for forming TEG are becoming smaller and smaller, however, a minute amount of capacitance and a minute amount of resistance between the gate electrode and active region cannot be measured with precision.

(3) The configuration of the interconnect line for connecting the pad and the MOS transistor is not symmetrical about a centerline defined between the pads. Due to this, in the implantation process of impurities into source/drain regions, for example, it is difficult to determine whether the direction of implantation is not at a tilt angle and whether a resist pattern is not formed in an improper position.

When the impurities are implanted at a tilt angle in the implantation process, it is likely that a region shaded with the gate electrode will be formed in the source/drain regions that is to be subjected to insufficient implantation. When the interconnect line is of symmetrical configuration, asymmetry of implantation between the source and the drain can be detected by switching positions between the source and the drain and applying voltage thereto for performing measurement, for example. When the interconnect line is not of symmetrical configuration, however, it cannot be determined whether occurrence of the region to be subjected to insufficient implantation results from the asymmetry of implantation or from the asymmetry of the configuration of the interconnect line. For this reason, such voltage measurement is made impractical.

### SUMMARY OF THE INVENTION

It is an object of the present invention to provide a semiconductor device holding in-line TEG's mounted thereon including TEG allowing reduction in influence exerted by resistance in interconnect line to a pad, TEG allowing precise measurement of minute amount of capacitance between a gate electrode and an active region in a MOS structure or TEG allowing symmetry of an interconnect line between pads for connecting a pad and a transistor. It is still an object of the present invention to provide a method of automatically arranging transistors for forming TEG in in-line TEG's.

According to the present invention, the semiconductor device includes a pad and a plurality of transistors arranged in a line for forming TEG, each of the plurality of transistors having a first current electrode, a second current electrode and a control electrode. In the semiconductor device, respective first current electrodes of the plurality of transistors are commonly connected to the pad by an interconnect line and the plurality of transistors are arranged from closer part to the pad in descending order of current-driving capability.

According to the present invention, the plurality of transistors are arranged from closer part to the pad in descending order of current-driving capability. Therefore, one transistor arranged farther from the pad than other transistor has a current-driving capability smaller than that of the other. As a result, the current value of the transistor becomes lower as the distance between the pad and the transistor increases, thereby allowing reduction in influence on the transistor characteristics that is exerted by voltage drop due to interconnection resistance.

Preferably, in the semiconductor device, the plurality of transistors are MOS transistors each having a source electrode, a drain electrode and a gate electrode respectively corresponding to the first current electrode, the second current electrode and the control electrode. And the plurality of transistors are arranged from the closer part in descending order of value obtained by dividing a gate width of the gate electrode by a gate length thereof.

According to the present invention, when the plurality of transistors are MOS transistors, the same effect as above described can be obtained.

According to the present invention, the method of arranging transistors for forming TEG in a layout design includes the following steps of (a) to (c). The transistors are a plurality of transistors arranged in a line each having a first current electrode, a second current electrode and a control electrode. The step (a) is determining specifications of the plurality of transistors to be arranged in the TEG. The step (b) is comparing the plurality of transistors in level of current-driving capability. And the step (c) is arranging the plurality of transistors in descending order of current-driving capability from closer part to the pad to which respective first current electrodes of the plurality of transistors are commonly connected by an interconnect line.

According to the present invention, the plurality of transistors are arranged from closer part to the pad in descending order of current-driving capability. As a result, the method of arranging transistors for forming TEG is realized that facilitates formation of the semiconductor device above described.

Preferably, in the method, the plurality of transistors are MOS transistors each having a source electrode, a drain electrode and a gate electrode respectively corresponding to the first current electrode, the second current electrode and the control electrode, and in the step (c), the plurality of transistors are arranged from the closer part in descending order of value obtained by dividing a gate width of the gate electrode by a gate length thereof.

According to the present invention, when the plurality of transistors are MOS transistors, the same effect as above described can be obtained.

According to the present invention, the semiconductor device includes a pad and a plurality of transistors for forming TEG, each of the plurality of transistors having a first current electrode, a second current electrode and a control electrode. In the semiconductor device, respective first current electrodes of the plurality of transistors are commonly connected to the pad by an interconnect line, and each of the plurality of transistors satisfies following equation:

$$N R ≦ \frac{r}{R S H \cdot S g}$$

where NR is the number of sheets in the interconnect line, RSH is sheet resistance in the interconnect line, Sg is conductance obtained by differentiating a current value between first and second current electrodes with respect to a voltage value between control electrode and first current electrode, and r is a value obtained by dividing the amount of reduction in current resulting from resistance in the interconnect line by a current value between first and second current electrodes.

According to the present invention, each of the plurality of transistors satisfies following equation:

$$N R ≦ \frac{r}{R S H \cdot S g}$$

The value of r corresponding to a rate of current reduction due to interconnection resistance is set at a permissible level and each value of NR, RSH and Sg is set to satisfy the foregoing equation. As a result, influence on the transistor characteristics that is exerted by voltage drop due to interconnection resistance is reduced.

According to the present invention, in the method of arranging transistors for forming TEG in a layout design, the transistors are a plurality of transistors each having a first current electrode, a second current electrode and a control electrode. In the method, respective first current electrodes of the plurality of transistors are commonly connected to a pad. The method comprises the following steps of (a) to (c). The step (a) is determining specifications of the plurality of transistors to be arranged in the TEG. The step (b) is determining whether each of the plurality of transistors satisfies following equation:

$$N R ≦ \frac{r}{R S H \cdot S g}$$

where NR is the number of sheets in the interconnect line, RSH is sheet resistance in the interconnect line, Sg is conductance obtained by differentiating a current value between first and second current electrodes with respect to a voltage value between control electrode and first current electrode, and r is a value obtained by dividing the amount of reduction in current resulting from resistance in the interconnect line by a current value between first and second current electrodes. The step (c) is removing a transistor that is determined to achieve no satisfaction of the equation in the step (b) and arranging a remaining transistor.

According to the present invention, the transistors are so arranged that each satisfies the following equation:

$$N R ≦ \frac{r}{R S H \cdot S g}$$

As a result, the method of arranging transistors for forming TEG is realized that facilitates formation of the semiconductor device above described.

According to the present invention, the semiconductor device includes a plurality of pads and a plurality of transistors for forming TEG arranged to be in line with the plurality of pads, each of the plurality of transistors having a first current electrode, a second current electrode and a control electrode. In the semiconductor device, respective first current electrodes of the plurality of transistors are commonly connected to one of the plurality of pads by an interconnect line, respective second current electrodes of the plurality of transistors are independently connected to remaining ones of the plurality of pads separate from each other, and the interconnect line is placed above or below the pads having connection to the second current electrodes without contact therebetween.

According to the present invention, the interconnect line is placed above or below the pads having connection to the second current electrodes without contact therebetween. Therefore, the width of the interconnect line is increased and interconnection resistance is reduced. As a result, influence on the transistor characteristics that is exerted by voltage drop due to interconnection resistance is reduced.

According to the present invention, the semiconductor device includes a pad and at least two transistors for forming TEG arranged to be in line with the pad, each of the at least two transistors having a first current electrode, a second current electrode and a control electrode. In the semiconductor device, the pad is arranged between the at least two transistors, and the pad is connected to respective first current electrodes of the at least two transistors arranged on both sides thereof by respective interconnect lines.

According to the present invention, the pad is connected to respective first current electrodes of the transistors arranged on both sides thereof by respective interconnect lines. Therefore, it is not required to elongate and route the interconnect line for connecting the first current electrodes and the pad laterally along the pad, thereby allowing increase in width of the interconnect line and reduction in interconnection resistance. As a result, influence on the transistor characteristics that is exerted by voltage drop due to interconnection resistance is reduced.

According to the present invention, the semiconductor device includes at least two pads and one or a plurality of transistors for forming TEG, each of the one or the plurality of transistors having a first current electrode, a second current electrode and a control electrode. In the semiconductor device, the one or the plurality of transistors are arranged between the at least two pads to be in line with the at least two pads, and the one or the plurality of transistors are arranged axially symmetrically about a centerline as an axis of symmetry defined between the at least two pads.

According to the present invention, one or the plurality of transistors are axially symmetrical about a centerline as an axis of symmetry defined between the at least two pads. Therefore, it is possible to realize TEG including the interconnect line for connecting the pads and transistors and having a configuration that is symmetrical about a centerline between the pads. Accompanied by this, when the first current electrode of one transistor is connected to one of the at least two pads by an interconnect line and the second current electrode of the same is connected to the other one of the pads by an interconnect line, the first current electrode and the second current electrode can provide respective resistances that are same in value. As a result, in an implantation process of impurities into source/drain regions, for example, it is possible to determine whether the direction of implantation is not at a tilt angle and whether a resist pattern is not formed in an improper position.

According to the present invention, the semiconductor device includes a plurality of gate electrodes arranged in parallel and an active region cutting across the plurality of gate electrodes. In the semiconductor device, source regions and drain regions are alternately provided to the active region between the plurality of gate electrodes.

According to the present invention, the source regions and the drain regions are alternately provided to the active region cutting across the plurality of gate electrodes. Therefore, as compared with the arrangement requiring separate MOS transistors to be in parallel, MOS transistors can be aligned in a more minute area. Further, the structure requiring the plurality of gate electrodes allows increase in area between the gate electrode and the active region. As a result, capacitance between the gate electrode and the active region and leakage current flowing therebetween can be measured with precision.

Preferably, the semiconductor device further includes a source interconnect line placed to be perpendicular to the plurality of gate electrodes for establishing connection between the source regions and a drain interconnect line placed to be perpendicular to the plurality of gate electrodes for establishing connection between the drain regions.

According to the present invention, the source interconnect line and the drain interconnect line are placed to be perpendicular to the plurality of gate electrodes. Therefore, as compared with the structure placing the source interconnect line and the drain interconnect line on a slanting direction relative to the direction in which the gate electrodes extend, the source interconnect line and the drain interconnect line are allowed to have their shortest possible lengths. As a result, interconnection resistance in the source interconnect line and the drain interconnect line can be kept at a minimum.

Preferably, in the semiconductor device, the plurality of gate electrodes are classified into at least two types and each of the at least two types has connection to a pad.

According to the present invention, the plurality of gate electrodes are classified into at least two types and each of these at least two types has connection to a pad. Therefore, the gate electrodes belonging to these two types can be treated as respective gate electrodes of separate MOS transistors. Further, it is only required to add one pad for gate electrode for increasing the number of MOS transistors in TEG without the need to increase the area for active region.

Preferably, in the semiconductor device, at least one of the plurality of gate electrodes has ends defined in a gate width direction each connected to a pad.

According to the present invention, at least one of the plurality of gate electrodes has ends defined in a gate width direction each connected to a pad. Therefore, fine-line interconnection resistance in the gate electrode can be evaluated by measuring the amount of voltage drop in the gate electrode. Further characteristically, when the plurality of gate electrodes are all of the same shape, voltage drop in each gate electrode is measured to evaluate resistance matching in gate electrode.

Preferably, in the semiconductor device, the plurality of gate electrodes are different from each other in gate size, the plurality of gate electrodes are respectively connected to pads, and layers to include the pads are provided at different levels according to difference in the gate size.

According to the present invention, the layers to include the pads are provided at different levels according to difference in the gate size. As a result, in the process of stacking interlayer insulating films while forming MOS transistors having different gates in size, the characteristics of the MOS transistors having the different gates in size can be proved in each layer.

According to the present invention, the semiconductor device includes a gate electrode and a plurality of active regions arranged in parallel, each of the plurality of active regions cutting across the gate electrode.

According to the present invention, the plurality of active regions are arranged in parallel and each of the plurality of active regions cuts across the gate electrode. Therefore, as compared with the structure requiring an extensive active region, the amount of dishing can be reduced that is caused by a CMP process, for example. As a result, a MOS transistor having a stable shape can be provided.

Preferably, in the semiconductor device, the gate electrode has ends defined in a gate width direction each connected to a pad.

According to the present invention, the gate electrode has ends defined in a gate width direction each connected to a pad. As a result, it is allowed to evaluate fine-line interconnection resistance in the gate electrode by measuring the amount of voltage drop in the gate electrode.

Preferably, in the semiconductor device, at least one of the plurality of active regions serves as a dummy active region not to be used as a device.

According to the present invention, at least one of the plurality of active regions serves as a dummy active region not to be used as a device. Therefore, a MOS transistor of a minute size can be provided including a gate electrode having a small gate width. As a result, formation of a transistor suffering from excessive flow of source-to-drain current can be avoided.

According to the present invention, the method of arranging transistors for forming TEG in a layout design includes the following steps of (a) and (b). The step (a) is arranging a plurality of pads. And the step (b) is arranging a plurality of transistors for forming the TEG to be in line with the plurality of pads, each of the plurality of transistors having a first current electrode, a second current electrode and a control electrode. In the method, respective first current electrodes of the plurality of transistors are commonly connected to one of the plurality of pads by an interconnect line, respective second current electrodes of the plurality of transistors are independently connected to remaining ones of the plurality of pads separate from each other, and the interconnect line is placed above or below the pads having connection to the second current electrodes without contact therebetween.

According to the present invention, the method of arranging transistors for forming TEG is provided for facilitating formation of the semiconductor device above described.

According to the present invention, the method of arranging transistors for forming TEG in a layout design includes the following steps of (a) and (b). The step (a) is arranging a pad. And the step (b) is arranging at least two transistors for forming TEG to be in line with the pad, each of the at least two transistors having a first current electrode, a second current electrode and a control electrode. In the method, the pad is arranged between the at least two transistors, and the pad is connected to respective first current electrodes of the at least two transistors arranged on both sides thereof by respective interconnect lines.

According to the present invention, the method of arranging transistors for forming TEG is provided for facilitating formation of the semiconductor device above described.

According to the present invention, the method of arranging transistors for forming TEG in a layout design includes the following steps of (a) and (b). The step (a) is arranging at least two pads. And the step (b) is arranging one or a plurality of transistors for forming the TEG, each of the one or the plurality of transistors having a first current electrode, a second current electrode and a control electrode. In the method, the one or the plurality of transistors are arranged between the at least two pads to be in line with the at least two pads, and the one or the plurality of transistors are arranged axially symmetrically about a centerline as an axis of symmetry defined between the at least two pads.

According to the present invention, the method of arranging transistors for forming TEG is provided for facilitating formation of the semiconductor device.

According to the present invention, the method of arranging transistors for forming TEG in a layout design includes the following steps of (a) and (b). The step (a) is arranging a plurality of gate electrodes in parallel. And the step (b) is arranging an active region to cut across the plurality of gate electrodes. In the method, source regions and drain regions are alternately provided to the active region between the plurality of gate electrodes.

According to the present invention, the method of arranging transistors for forming TEG is provided for facilitating formation of the semiconductor device above described.

Preferably, the method further includes the following steps of (c) and (d). The step (c) is placing a source interconnect line to be perpendicular to the plurality of gate electrodes for establishing connection between the source regions. And the step (d) is placing a drain interconnect line to be perpendicular to the plurality of gate electrodes for establishing connection between the drain regions.

According to the present invention, the method of arranging transistors for forming TEG is provided for facilitating formation of the semiconductor device above described.

Preferably, in the method, the plurality gate electrodes are classified into at least two types and each of the at least two types has connection to a pad.

According to the present invention, the method of arranging transistors for forming TEG is provided for facilitating formation of the semiconductor device above described.

Preferably, in the method, at least one of the plurality of gate electrodes has ends defined in a gate width direction each connected to a pad.

According to the present invention, the method of arranging transistors for forming TEG is provided for facilitating formation of the semiconductor device above described.

Preferably, in the method, the plurality of gate electrodes are different from each other in gate size, the plurality of gate electrodes are respectively connected to pads, and layers to include the pads are provided at different levels according to difference in the gate size.

According to the present invention, the method of arranging transistors for forming TEG is provided for facilitating formation of the semiconductor device above described.

According to the present invention, the method of arranging transistors for forming TEG in a layout design includes the following steps of (a) and (b). The step (a) is arranging a gate electrode. And the step (b) is arranging a plurality of active regions in parallel, each of the plurality of active regions cutting across the gate electrode.

According to the present invention, the method of arranging transistors for forming TEG is provided for facilitating formation of the semiconductor device above described.

Preferably, in the method, the gate electrode has ends defined in a gate width direction each connected to a pad.

According to the present invention, the method of arranging transistors for forming TEG is provided for facilitating formation of the semiconductor device above described.

Preferably, in the method, at least one of the plurality of active regions serves as a dummy active region not to be used as a device.

According to the present invention, the method of arranging transistors for forming TEG is provided for facilitating formation of the semiconductor device above described.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view exemplifying the structure of a semiconductor device according to a first preferred embodiment of the present invention;

FIG. 2 is a flow chart showing a method of arranging transistors for forming TEG according to the first preferred embodiment of the present invention;

FIG. 3 is a flow chart showing a method of arranging transistors for forming TEG according to a second preferred embodiment of the present invention;

FIG. 4 is a view exemplifying the structure of a semiconductor device according to a third preferred embodiment of the present invention;

FIG. 5 is a sectional view illustrating the structure of the semiconductor device according to the third preferred embodiment of the present invention;

FIG. 6 is a view exemplifying the structure of a semiconductor device according to a four th preferred embodiment of the present invention;

FIG. 7 is a view illustrating parasitic resistances of a MOS transistor;

FIG. 8 is a view exemplifying an alternative structure of the semiconductor device according to the fourth preferred embodiment of the present invention;

FIG. 9 is a view exemplifying the structure of a semiconductor device according to a fifth preferred embodiment of the present invention;

FIG. 10 is a view exemplifying an alternative structure of the semiconductor device according to the fifth preferred embodiment of the present invention;

FIG. 11 is a view exemplifying the structure of a semiconductor device according to a sixth preferred embodiment of the present invention;

FIGS. 12 and 13 are views exemplifying alternative structures of the semiconductor device according to the sixth preferred embodiment of the present invention;

FIG. 14 is a view illustrating a TEG-forming region on a wafer;

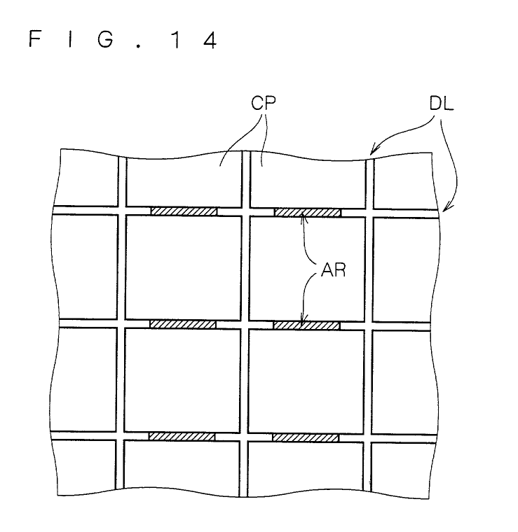

FIG. 15 is a view exemplifying the structure of TEG for forming in-line TEG's in the background art;

FIG. 16 is a view illustrating parasitic resistances of a MOS transistor; and

FIGS. 17 and 18 are graphs showing the characteristics of a transistor affected by interconnection resistance added thereto.

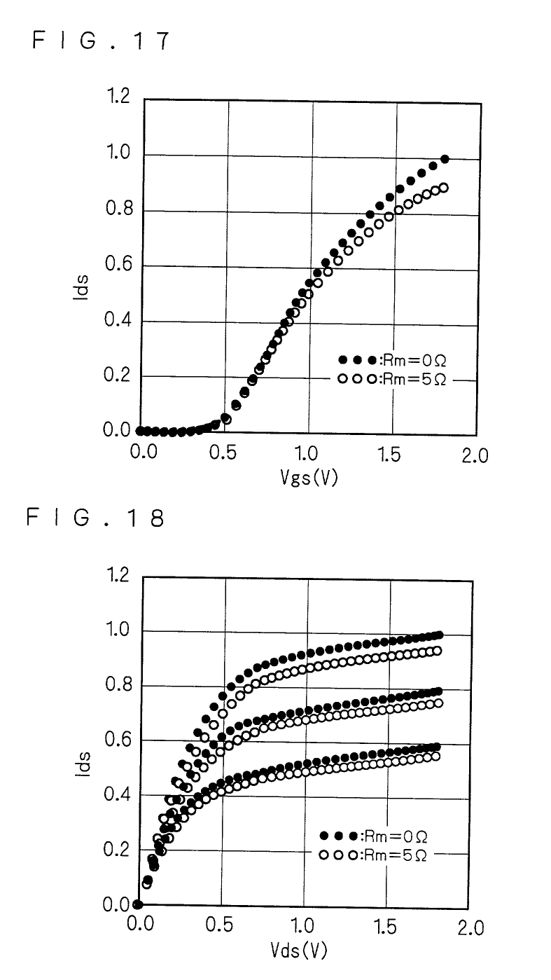

### DESCRIPTION OF THE PREFERRED EMBODIMENTS

<First Preferred Embodiment>

The first preferred embodiment of the present invention requires that a plurality of transistors are arranged from closer part to a pad in descending order of current-driving capability, to thereby realize a semiconductor device holding in-line TEG's mounted thereon allowing reduction in influence exerted by resistance in interconnect line to the pad.

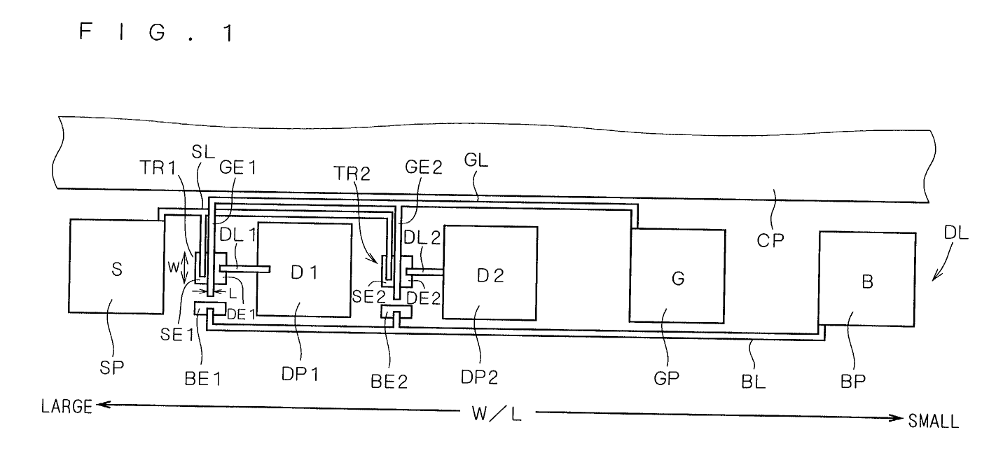

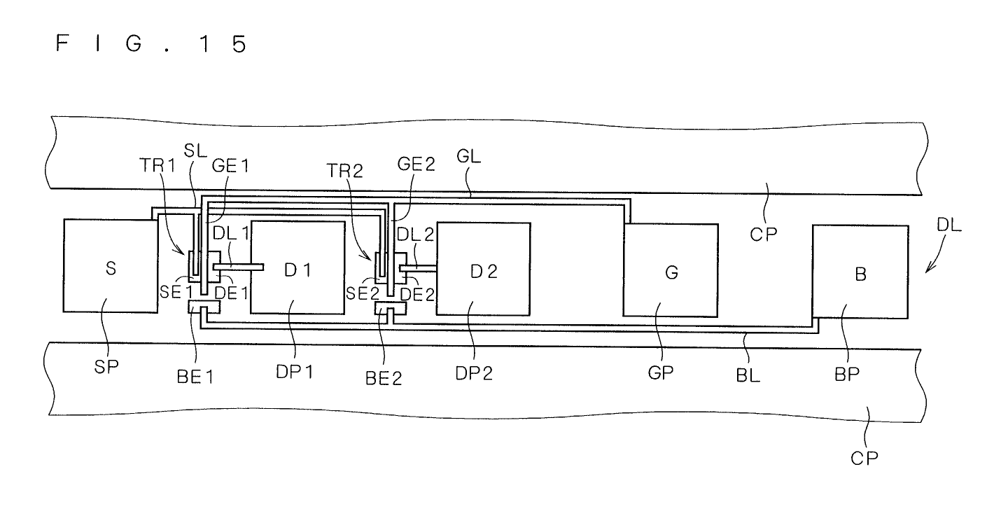

FIG. 1 is a view exemplifying the structure of a semiconductor device according to the first preferred embodiment. The TEG illustrated in FIG. 1 for forming in-line TEG's mounted on the semiconductor device according to the first preferred embodiment includes the MOS transistors TR1 and TR2 each serving as a device and having the same structure as illustrated in FIG. 15. Also illustrated in FIG. 1 are the pads SP, DP1, DP2, GP and BP for respectively supplying potential to the source electrodes SE1, SE2 of the transistors TR1, TR2, to the drain electrode DE1 of the transistor TR1, to the drain electrode DE2 of the transistor TR2, to gate electrodes GE1, GE2 of the transistors TR1, TR2 and to the body electrodes BE1, BE2 of the transistors TR1, TR2. The pad SP for source electrode, the pad GP for gate electrode and the pad BP for body electrode are shared between the MOS transistors TR1 and TR2. In contrast, the pads DP1 and DP2 for drain electrode are provided for the respective MOS transistors. Each pad and electrode are interconnected by the interconnect lines SL, GL, BL, DL1 and DL2.

In the first preferred embodiment, the MOS transistors TR1 and TR2 are arranged from closer part to the pad SP in descending order of current-driving capability of transistor. That is, when the transistor has a MOS structure, the MOS transistors are arranged from closer part to the pad SP in descending order of value obtained by dividing a gate width W of a gate electrode by a gate length L of the same (namely, in descending order of value of W/L).

When the MOS transistor has a large current-driving capability, the value of current flowing between the source and the drain is high. Consequently, if the MOS transistor having a large current-driving capability is positioned away from the pad for source electrode, the amount of voltage drop developed in the interconnect line for connecting the pad and the source electrode is increased. For this reason, it is desirable that the MOS transistors are arranged from closer part to the pad for source electrode in descending order of current-driving capability, to thereby reduce the amount of voltage drop in the interconnect line.

As described so far, in the semiconductor device according to the first preferred embodiment, one transistor arranged farther from the pad than other transistor has a current-driving capability smaller than that of the other. Therefore, the current value of the transistor becomes lower as the distance between the pad and the transistor increases. As a result, influence on the transistor characteristics that is exerted by voltage drop due to interconnection resistance is reduced.

While the first preferred embodiment employs transistor of a MOS structure, an alternative type of transistor such as bipolar transistor is applicable as well by arranging bipolar transistors in the same way as MOS transistors. More particularly, when the bipolar transistor is employed, for example, a current-driving capability of the bipolar transistor becomes larger as a value of WB/LB expressing a ratio between a base width WB and a diffusion length LB of an electron injected into a base decreases. Therefore, the transistors are arranged from closer part to a pad for emitter electrode corresponding to a source electrode in order of their increasing value of WB/LB.

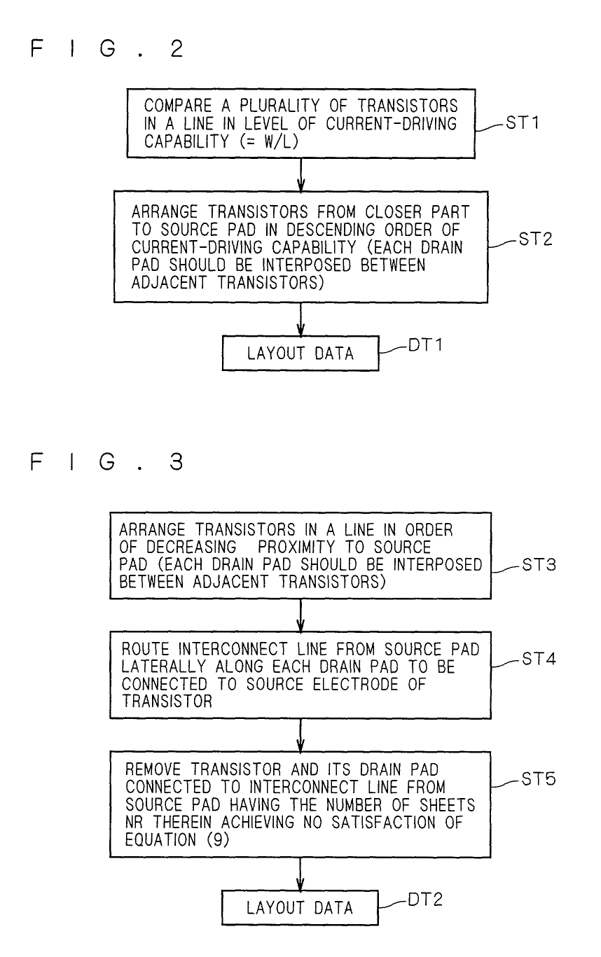

Next, a method of automatically arranging transistors for forming TEG in the above-mentioned in-line TEG's in a wafer will be described that is to be employed in designing layout of the wafer using a computer. FIG. 2 is a flow chart showing this method of arranging transistors. The specifications of the transistor to be arranged in the TEG are defined to be predetermined.

As shown in FIG. 2, MOS transistor devices included in the TEG in the in-line TEG's to be formed are compared first in level of current-driving capability (step ST1). When the transistor has a MOS structure, this comparison is made by comparing values of W/L obtained by dividing a gate width W by a gate length L.

Next, the MOS transistors are arranged in a line from closer part to the pad for establishing connection to source electrode in descending order of current-driving capability (step ST2). In this step, each drain pad should be interposed between the adjacent transistors. Layout data DT1 is thereby obtained.

Following this method of arranging transistors for forming TEG, formation of the semiconductor device holding the afore-mentioned in-line TEG's mounted thereon is facilitated.

The foregoing method of arranging transistors for forming TEG can be facilitated by using a computer system including CPU (central processing unit), ROM (read only memory), RAM (random access memory), input/output device such as keyboard and display and external memory device such as hard disk.

<Second Preferred Embodiment>

The second preferred embodiment of the present invention requires that a plurality of transistors respectively satisfy specific equations, to thereby realize a semiconductor device holding in-line TEG's mounted thereon allowing reduction in influence exerted by resistance in interconnect line to the pad.

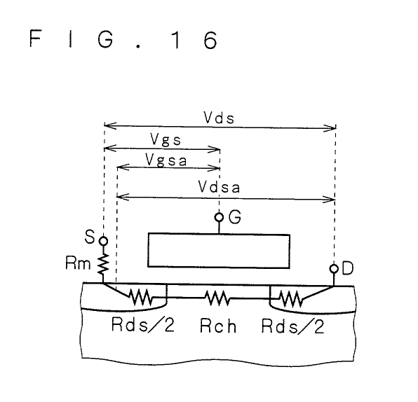

In the following description, influence exerted by resistance in interconnect line SL to the pad SP is quantitatively calculated using FIG. 16 when the TEG for forming the in-line TEG's includes the MOS transistors TR1 and TR2 each having the same structure as illustrated in FIG. 15. When the interconnection resistance Rm is added to the source side (S), designating a source-to-drain voltage as Vds and a source-to-gate voltage as Vgs, biases Vdsa and Vgsa effectively applied to the MOS transistor are expressed by the following equations (1) and (2):

Vdsa=Vds−ΔV (1)

Vgsa=Vgs−ΔV (2)

Designating a source-to-drain current as Ids, ΔV satisfies the following equation (3):

ΔV=Rm·Ids (3)

That is, the effective source-to-drain voltage Vdsa and the effective source-to-gate voltage Vgsa have their respective values both subjected to voltage drop corresponding to ΔV. The source-to-drain current Ids is reduced accordingly.

The amount of influence on the source-to-drain current Ids includes ΔIdsg caused by the source-to-gate voltage Vgs and ΔIdsd caused by the source-to-drain voltage Vds. The amounts ΔIdsg and ΔIdsd are estimated by the following equation (4) and (5):

ΔIdsg=ΔV·Sg=Rm·Ids·Sg (4)

ΔIdsd=ΔV·Sd=Rm·Ids·Sd (5)

In these equations, Sg and Sd are conductances satisfying the following respective equations (6) and (7):

$$\begin{matrix}S g = \frac{\partial I d s}{\partial V g s} & ( 6 ) \\ S d = \frac{\partial I d s}{\partial V d s} & ( 7 )\end{matrix}$$

In terms of conductance, a relation of Sd<<Sg is established. Therefore, in terms of the amount of influence, only the value of ΔIdsg should be given consideration. For this reason, regarding ΔIdsg obtained by the equation (4) as ΔIds, multiplication and division is performed as expressed in the following equation (8):

$$r ≡ \frac{Δ I d s}{I d s} ≅ R m \cdot S g \qquad ( 8 )$$

In the equation (8), r is a value obtained by dividing the amount of reduction in current (or amount of drop in current) by the value of the source-to-drain current, namely, corresponding to a current reduction rate defined by ΔIds/Ids. When the values of Rm and Sg are respectively 5Ω and 5 mA/V, for example, the current reduction rate r is calculated to be 2.5%.

Considering the current reduction rate r as the influence exerted by resistance in the interconnect line SL, layout design is performed in such a way that the current reduction rate r will have a value equal to or smaller than a certain value. As a result, in-line TEG's are realized allowing reduction in reducing influence exerted by resistance in interconnect line to the pad.

More particularly, the number of sheets each having a sheet resistance in interconnect line is limited on the basis of (8) so that the current reduction rate r can be controlled to have a value falling within a certain range. Designating the sheet resistance and the number of sheets in interconnect line as RSH and NR, respectively, the relation of Rm=RSH·NR is established. Therefore, the number of sheets NR is required to satisfy the following equation (9):

$$N R ≦ \frac{r}{R S H \cdot S g} \qquad ( 9 )$$

When the values of RSH, Sg are respectively 0.1Ω/□, 5 mA/V and r≦2.0%, for example, it is given that the number of sheets NR is ≦40. That is, in in-line TEG's, when the interconnect line SL includes a portion for connecting the MOS transistor TR1 to the pad SP and a portion for connecting the MOS transistor TR2 to the pad SP each satisfying the relation of NR≦40, interconnection resistance in the TEG causes little influence.

As described so far, under the condition that the current reduction rate r has a permissible value and the values of NR, RSH, Sg all satisfy the foregoing equations, influence on the transistor characteristics that is exerted by voltage drop due to interconnection resistance is reduced.

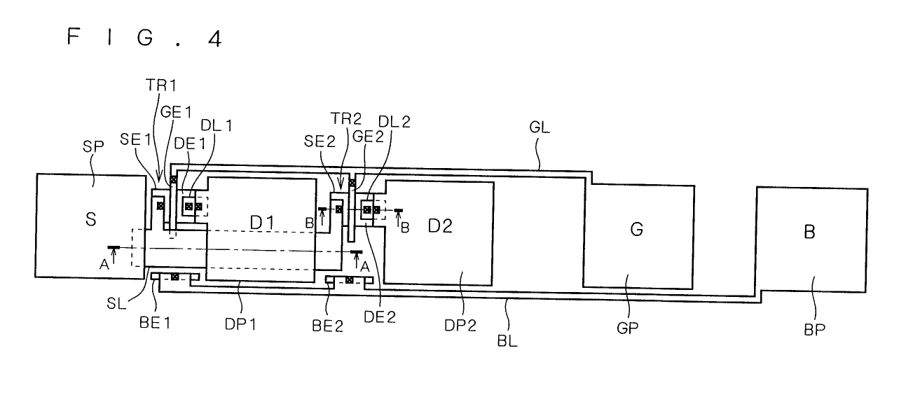

Next, a method of automatically arranging transistors for forming TEG in the above-mentioned in-line TEG's in a wafer will be described that is to be employed in designing layout of the wafer using a computer. FIG. 3 is a flow chart showing this method of arranging transistors. The specifications of the transistor to be arranged in the TEG are defined to be predetermined.

As shown in FIG. 3, MOS transistors included in TEG in the in-line TEG's to be formed are arranged in a line in order of decreasing proximity to the pad for establishing connection to source electrode (step ST3). In this step, each drain pad should be interposed between the adjacent transistors.

Next, the interconnect line from the source pad is routed laterally along each drain pad to establish connection to the source electrode of each MOS transistor (step ST4). At this time, the MOS transistor and its drain pad are removed that are connected to the interconnect line from the source pad having the number of sheets NR therein achieving no satisfaction of equation (9) (step ST5). Layout data DT2 is thereby obtained.

Following this method of arranging transistors for forming TEG, the formation of the semiconductor device holding the afore-mentioned in-line TEG's mounted thereon is facilitated.

The foregoing method of arranging transistors for forming TEG can be facilitated by using a computer system including CPU, ROM, RAM, input/output device such as keyboard and display and external memory device such as hard disk.

<Third Preferred Embodiment>

The third preferred embodiment of the present invention requires that the interconnect line to the source pad is placed above or below the drain pad without contact therebetween, to thereby increase the width of the interconnect line and reduce interconnection resistance. As a result, a semiconductor device holding in-line TEG's mounted thereon is provided allowing reduction in influence on the transistor characteristics exerted by voltage drop due to interconnection resistance.

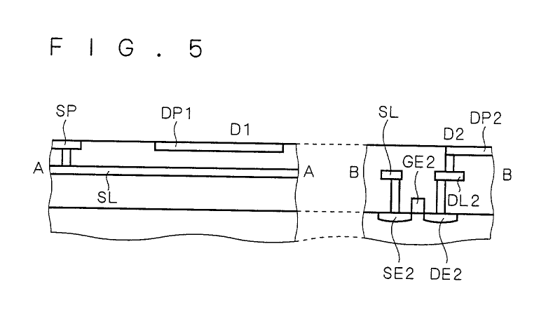

FIG. 4 is a view exemplifying the structure of a semiconductor device according to the third preferred embodiment. The TEG illustrated in FIG. 4 for forming in-line TEG's mounted on the semiconductor device according to the third preferred embodiment includes the MOS transistors TR1 and TR2 each serving as a device and having the same structure as illustrated in FIG. 15. Also illustrated in FIG. 4 are the pads SP, DP1, DP2, GP and BP for respectively supplying potential to the source electrodes, drain electrodes, gate electrodes and body electrodes of the transistors TR1 and TR2. The pad SP for source electrode, the pad GP for gate electrode and the pad BP for body electrode are shared between the MOS transistors TR1 and TR2. In contrast, the pads DP1 and DP2 for drain electrode are provided for the respective MOS transistors TR1 and TR2. Each pad and electrode are interconnected by the interconnect lines SL, GL, BL, DL1 and DL2.

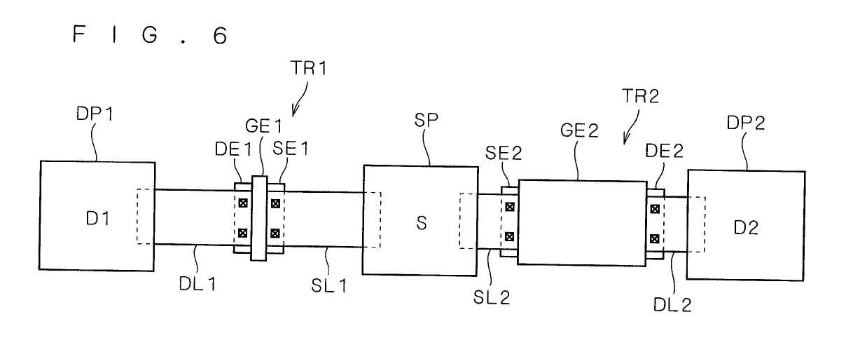

In the third preferred embodiment, the interconnect line SL to the source pad SP is placed below the drain pad DP1 without contact therebetween as illustrated in the sectional view of FIG. 5. In FIG. 5, a cross section taken along a cutting line A-A and a cross section along a cutting line B-B are illustrated in the same plane.

When the interconnect line SL is placed below the drain pad DP1 without contact therebetween, it is not required to elongate and route the interconnect line SL laterally along the drain pad DP1 as illustrated in FIG. 15. Therefore, the width of the interconnect line can be increased and interconnection resistance is reduced, thereby allowing reduction in influence on the transistor characteristics that is exerted by voltage drop due to interconnection resistance.

While the third preferred embodiment requires that the interconnect line SL is placed below the drain pad DP1, the interconnect line SL may be placed above the drain pad DP1 without contact therebetween. This placement also realizes a semiconductor device holding in-line TEG's mounted thereon achieving the same effect as described above.

<Fourth Preferred Embodiment>

The fourth preferred embodiment of the present invention requires that the source pad is arranged between two MOS transistors, to thereby increase the width of the interconnect line to the source pad and reduce interconnection resistance. As a result, a semiconductor device holding in-line TEG's mounted thereon is provided allowing reduction in influence on the transistor characteristics exerted by voltage drop due to interconnection resistance.

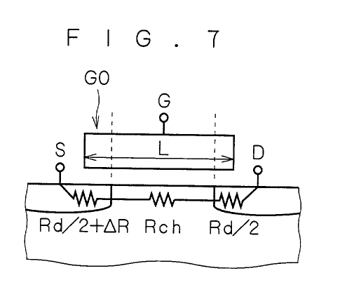

FIG. 6 is a view exemplifying the structure of a semiconductor device according to the fourth preferred embodiment. The TEG illustrated in FIG. 6 for forming in-line TEG's mounted on the semiconductor device according to the fourth preferred embodiment includes the MOS transistors TR1 and TR2 each serving as a device and having the same structure as illustrated in FIG. 15. Also illustrated in FIG. 6 are the pads SP and DP1, DP2 for respectively supplying potential to the source electrodes and the drain electrodes of the transistors TR1 and TR2. The pad SP for source electrode is shared between the MOS transistors TR1 and TR2. In contrast, the pads DP1 and DP2 for drain electrode are provided for the respective MOS transistors TR1 and TR2. Each pad and electrode are interconnected by interconnect lines SL1, SL2 and by the interconnect lines DL1, DL2.

As illustrated in FIG. 6, the fourth preferred embodiment requires that the two MOS transistors TR1 and TR2 form a line together with the pads SP, DP1 and DP2. Further, the source pad SP is interposed between the two transistors TR1 and TR2. The source pad SP is connected to respective source electrodes of the transistors TR1 and TR2 arranged on both sides thereof by the respective interconnect lines SL1 and SL2.

Following this arrangement requiring the source pad SP to be interposed between the two transistors TR1 and TR2, it is not necessary to elongate and route the interconnect line for connecting the source electrode and the source pad laterally along the drain pad. Therefore, the width of the interconnect line can be increased and interconnection resistance is reduced, thereby allowing reduction in influence on the transistor characteristics that is exerted by voltage drop due to interconnection resistance.

As a modification of the fourth preferred embodiment, one or a plurality of transistors may be axially symmetrical about a centerline as an axis of symmetry defined between at least two pads.

The asymmetry of the transistor characteristics resulting from the implantation process of impurities will be discussed. The asymmetry to be discussed refers to the asymmetry of the transistor characteristics such as Ids-Vds characteristics obtained by switching positions between the source and the drain for measuring characteristics when the transistor has a MOS structure. In the transistor of a MOS structure, for example, such asymmetry results from the fact that the source region and drain region receive different impurity implant doses. It is a matter of course that such asymmetry is undesirable.

The asymmetry resulting from the implantation process of impurities includes (1) asymmetry resulting from a direction of implantation of impurities and (2) asymmetry resulting from shadowing by photoresist.

The asymmetry (1) resulting from a direction of implantation of impurities is caused in a case where the direction of implantation of impurities into the wafer is not performed precisely along a specific direction. In such case, the direction of implantation may not be precisely along a line normal to the surface of the wafer, for example. In order to avoid the asymmetry (1), the implantation should be precisely performed into the source and the drain in a strictly symmetrical manner, requiring that the implantation should be performed over several times. This is likely to result in increase in complexity of process and increase in cost. For this reason, the asymmetry (1) is considered to be unavoidable to some degree at present.

The asymmetry (2) resulting from shadowing by photoresist is caused by the fact that even if the implantation is performed symmetrically, a mask set in an improper position when forming a pattern for the photoresist results in a region to be shaded with the photoresist. Due to this, implantation from a certain direction cannot be perfectly performed. In light of the present trend toward finer structure, the asymmetry (2) is also considered to be unavoidable to some degree.

In view of the above, it is required to evaluate asymmetry from these causes in the implantation process of impurities. For detection of the asymmetry, TEG including transistor should be of symmetrical configuration. Accompanied by this, the configuration of the interconnect line for establishing connection to each electrode of the transistor should be symmetrical. This is because when the interconnect line is not of symmetrical configuration, it cannot be determined whether the asymmetry of the characteristics results from the asymmetry of implantation or from the asymmetry of the configuration of the interconnect line.

Taking the MOS transistor in FIG. 16 as an example, measurement is performed switching positions between the source and the drain. The effective source-to-drain voltage Vdsa and the effective source-to-gate voltage (practically, drain-to-gate voltage) Vgsa are respectively obtained from the equations (10) and (11) as follows:

Vdsa=Vds−ΔV (10)

Vgsa=Vgs (11)

As understood from the equation (11), the value of the source-to-drain voltage Vgsa does not include voltage drop caused by the interconnection resistance Rm.

When the presence or absence of parasitic resistance is not the same between the source side and the drain side thereby causing asymmetry between the source and the drain, asymmetry of the characteristics such as source-to-drain current occurs. As a result, it becomes difficult to evaluate the aforementioned asymmetry resulting from the implantation process of impurities.

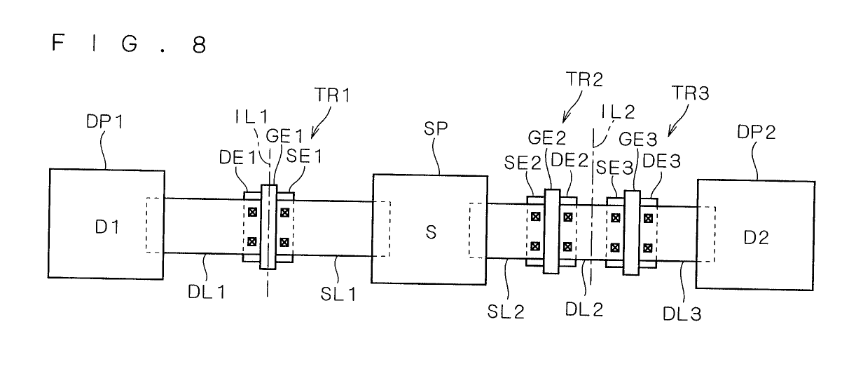

As illustrated in FIG. 7, further, when a gate overlapping portion GO has a dimension on the source side considerably larger than that on the drain side due to improper positioning of the mask, for example, parasitic resistance in the source side is increased by an increment of ΔR. In this case, the same problem as discussed with reference to FIG. 16 is also caused.

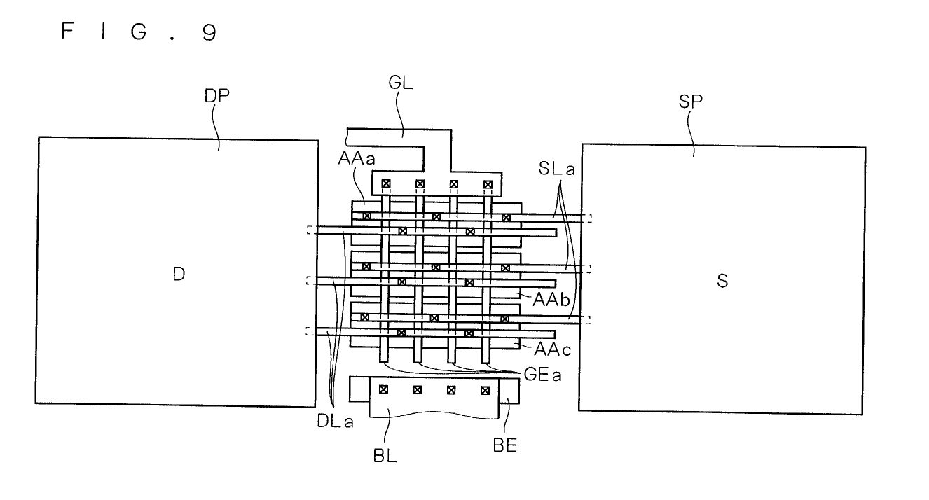

As a countermeasure against the above, one or a plurality of transistors should be axially symmetrical about a centerline as an axis of symmetry defined between at least two pads. FIG. 8 exemplifies the structure of TEG having such structure for forming in-line TEG's.

The TEG illustrated in FIG. 8 for forming in-line TEG's mounted on the semiconductor device according to the fourth preferred embodiment includes the MOS transistors TR1 and TR2 and further includes a MOS transistor TR3 each serving as a device and having the same structure as illustrated in FIG. 6. Also illustrated in FIG. 8 are the pads SP and DP1, DP2 for respectively supplying potential to the source electrodes and the drain electrodes of the transistors TR1, TR2 and TR3. The MOS transistor TR1 is interposed between the pads SP and DP1 for forming a line together with the pads SP and DP1. The MOS transistors TR2 and TR3 are interposed between the pads SP and DP2 for forming a line together with the pads SP and DP2. The drain electrode DE2 of the MOS transistor TR2 is connected to a source electrode SE3 of the MOS transistor TR3 by the interconnect line DL2.

The pad SP for source electrode is shared between the MOS transistors TR1 and TR2. In contrast, the pads DP1 and DP2 for drain electrode are provided for the respective MOS transistors TR1 and TR3. Each pad and electrode are interconnected by the interconnect lines SL1, SL2, DL1 and by an interconnect line DL3.

As illustrated in FIG. 8, the fourth preferred embodiment requires that the MOS transistor TR1 is of axially symmetrical configuration about a centerline IL1 as an axis of symmetry defined between the pads SP and DP1. The fourth preferred embodiment further requires that the MOS transistors TR2 and TR3 are symmetrical to each other about a centerline IL2 as an axis of symmetry defined between the pads SP and DP2.

When one or a plurality of transistors are of axially symmetrical configuration about a centerline as an axis of symmetry between two pads as discussed above, it is allowed to form TEG including the interconnect lines SL1, SL2 and DL1 through DL3 of symmetrical configuration between the pads for establishing connection between each pad and transistor. As a result, when a source electrode of a MOS transistor is connected to one pad by an interconnect line and a drain electrode of the MOS transistor is connected to the other pad by an interconnect line, for example, the source electrode and the drain electrode can provide respective resistances that are same in value. Therefore, in the implantation process of impurities into the source/drain regions, for example, it is possible to determine whether the direction of implantation is not at a tilt angle and whether a resist pattern is not formed in an improper position.

<Fifth Preferred Embodiment>

The fifth preferred embodiment of the present invention realizes a semiconductor device holding in-line TEG's including a plurality of gate electrodes cutting across an active region. The fifth preferred embodiment is further characteristic in that the active region includes a plurality of active regions arranged in parallel.

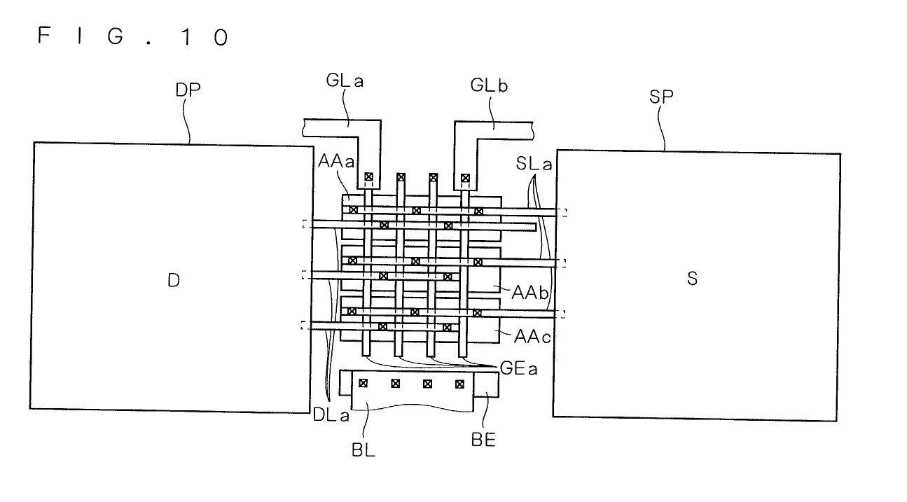

FIG. 9 is a view exemplifying the structure of a semiconductor device according to the fifth preferred embodiment. The TEG forming in-line TEG's held on the semiconductor device according to the fifth preferred embodiment includes a plurality of gate electrodes GEa arranged in parallel and a plurality of active regions AAa, AAb, AAc arranged in parallel to be perpendicular to the gate electrodes GEa. The plurality of active regions AAa, AAb and AAc respectively cut across the gate electrodes GEa.

Source regions and drain regions are alternately provided to each part of the active regions AAa, AAb and AAc between the plurality of gate electrodes GEa. Also provided are a source interconnect line SLa to be perpendicular to the gate electrodes GEa for establishing connection between the source regions and a drain interconnect line DLa to be perpendicular to the gate electrodes GEa for establishing connection between the drain regions.

The source interconnect line SLa is connected to the source pad SP and the drain interconnect line DLa is connected to the drain pad DP. The plurality of gate electrodes GEa are commonly connected to the gate interconnect line GL. Further, a body electrode BE is connected to the body interconnect line BL.

Although not shown, the gate interconnect line GL and the body interconnect line BL have respective connections to the pad for applying gate voltage and the pad for applying body voltage.

As illustrated in FIG. 9, the fifth preferred embodiment requires that the source regions and the drain regions are alternately provided to the active region AAa, AAb or AAc between the plurality of gate electrodes GEa. Therefore, as compared with the arrangement requiring separate MOS transistors to be in parallel (see the aligned MOS transistors TR2 and TR3 in FIG. 8, for example), the MOS transistors can be aligned in a more minute area.

Further, the structure requiring the plurality of gate electrodes GEa allows increase opposite area between the gate electrode and the active region. As a result, capacitance between the gate electrode and the active region and leakage current flowing therebetween can be measured with precision.

In addition, the structure according to the fifth preferred embodiment requires the plurality of active regions AAa, AAb and AAc to be arranged in parallel respectively cutting across the gate electrodes GEa. Therefore, as compared with the structure requiring an extensive active region, the amount of dishing can be reduced that is caused by a CMP (chemical mechanical polishing) process, for example. As a result, a MOS transistor having a stable shape can be provided as discussed below.

Taking the structure illustrated in FIG. 9 as an example, the active regions AAa, AAb and AAc may be combined into one active region having an extensive area without providing insulating region therebetween. When the CMP process is performed on such extensive active region, however, a dishing phenomenon causing depression at the center of the active region is likely to occur. The amount of dishing increases in proportion to the increase in area of the active region. As compared with the structure including the extensive active region, therefore, the dishing is less likely to occur in the structure dividing the active region into a plurality of active regions. This is the reason why the MOS transistor having a stable shape can be provided.

The fifth preferred embodiment is also characteristic in that the source interconnect line SLa and the drain interconnect line DLa are placed to be perpendicular to the plurality of gate electrodes GEa. Therefore, as compared with the structure placing the source interconnect line SLa and the drain interconnect line DLa on a slanting direction relative to the direction in which the gate electrodes GEa extend, the source interconnect line and the drain interconnect line are allowed to have their shortest possible lengths. As a result, the value of interconnection resistance in the source interconnect line and the drain interconnect line can be kept at a minimum.

Alternatively, the source interconnect line and the drain interconnect line may be placed in parallel with the gate electrode. However, the gate electrode should be formed at a submicron level and the space between the gate electrodes should be kept as small as possible. For this reason, it is practically difficult to arrange the source interconnect line and the drain interconnect line between the gate electrodes forming an interdigital structure as illustrated in FIG. 9. In contrast to this, the structure placing the source interconnect line and the drain interconnect line to be perpendicular to the gate electrode as discussed above allows the value of interconnection resistance to be reliably kept at a minimum.

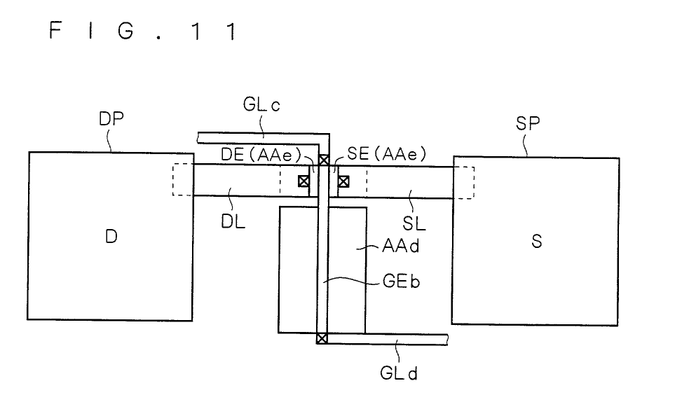

The semiconductor device according to the fifth preferred embodiment may have alternative structure as exemplified in FIG. 10. The structure of FIG. 10 is different from that of FIG. 9 in that the gate electrodes GEa are not commonly connected to the gate interconnect line GL. Taking the structure of FIG. 10 as an example, the gate electrodes GEa are classified into three types. These three types include the gate electrode GEa having connection to a first gate interconnect line GLa, the gate electrode GEa having connection to a second gate interconnect line GLb and the gate electrode GEa without connection to either the first gate interconnect line GLa or the second gate interconnect line GLb. The gate interconnect line GLa is connected to a first gate pad not shown and the gate interconnect line GLb is connected to a second gate pad not shown.

When the gate electrodes are classified into at least two types and the gate electrodes belonging to at least two types are respectively connected to the pads as discussed above, these gate electrodes can be each treated as respective gate electrodes of separate MOS transistors. Further, it is only required to add one pad for gate electrode for increasing the number of MOS transistors in TEG without the need to increase the area for active region.

In the structure illustrated in FIG. 10, the gate size of the gate electrode connected to the first gate interconnect line GLa and the gate size of the gate electrode connected to the second gate interconnect line GLb may be different from each other so that layers to include gate pads for respective electrode are provided at different levels.

Accordingly, in the process of stacking interlayer insulating films while forming MOS transistors having different gates in size, the characteristics of the MOS transistors having the different gates in size can be proved in each layer.

<Sixth Preferred Embodiment>

The sixth preferred embodiment of the present invention realizes a semiconductor device holding in-line TEG's including a plurality of active regions cutting across a gate electrode having ends defined in a gate width direction each connected to a pad.

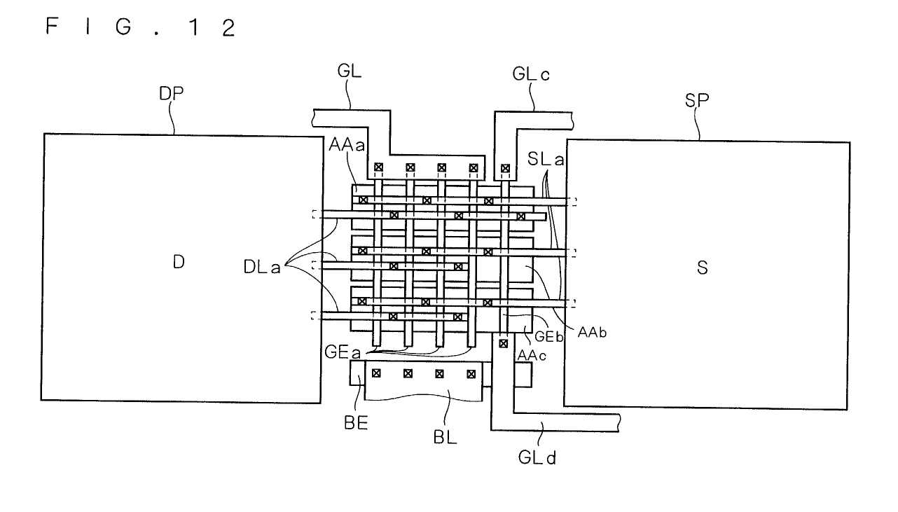

FIG. 11 is a view exemplifying the structure of a semiconductor device according to the sixth preferred embodiment. The TEG for forming in-line TEG's held on the semiconductor device according to the sixth preferred embodiment includes a gate electrode GEb and a plurality of active regions AAd, AAe arranged in parallel to be perpendicular to the gate electrode GEb. The plurality of active regions AAd and AAe respectively cut across the gate electrode GEb.

A source region SE and a drain region DE are provided to the active region AAe. Also provided are the source interconnect line SL to be perpendicular to the gate electrode GEb for establishing connection between the source region SE and the source pad SP, and the drain interconnect line DL to be perpendicular to the gate electrode GEb for establishing connection between the drain region DE and the drain pad DP.

One end of the gate electrode GEb defined in a gate width direction is connected to a first gate interconnect line GLc for establishing connection to a first gate pad (not shown) and the other end of the gate electrode GEb is connected to a second gate interconnect line GLd for establishing connection to a second gate pad (not shown).

When the gate electrode has ends defined in a gate width direction each connected to the pad, fine-line interconnection resistance (resistance in a gate width direction) in the gate electrode can be evaluated by measuring the amount of voltage drop in the gate electrode.

The active region AAd in FIG. 11 serves as a dummy active region not to be used as a device. Using the active region AAd as a dummy active region, a MOS transistor of a minute size can be provided including a gate electrode having a small gate width. That is, the gate width of the MOS transistor including the source region SE, the drain region DE and the gate electrode GEb is kept small. As a result, formation of a transistor suffering from excessive flow of source-to-drain current can be avoided.

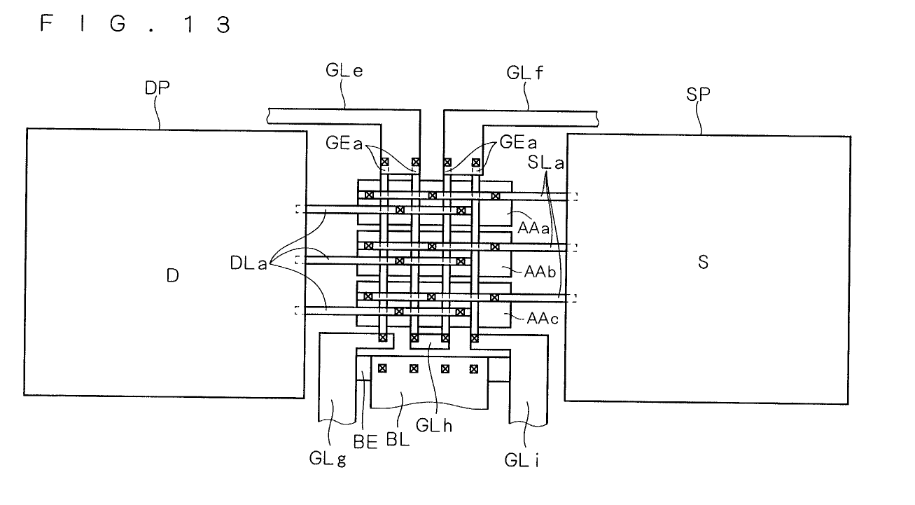

The TEG as illustrated in FIG. 11 allowing measurement of fine-line interconnection resistance in the gate electrode is also applicable to the semiconductor device according to the fifth preferred embodiment. FIG. 12 is a view exemplifying the structure formed by adding the structure of FIG. 11 to that of FIG. 9. In addition to the plurality of gate electrodes GEa, the structure of FIG. 12 includes the gate electrode GEb arranged in the portion to the right of the gate electrodes GEa and having ends respectively connected to the first and second gate interconnect lines GLc and GLd.

FIG. 13 is a view exemplifying the structure formed on the basis of the structure of FIG. 9. Instead of the gate interconnect line GL in FIG. 9 to which the plurality of gate electrodes GEa are commonly connected, the structure of FIG. 13 includes gate interconnect lines GLe, GLf, GLg, GLh and GLi for connecting the ends of the gate electrodes GEa in a zigzag manner. Except for the gate interconnect line GLh, the gate interconnect lines GLe, GLf, GLg and GLi are respectively connected to gate pads (not shown).

When at least one gate electrode of the plurality of gate electrodes has ends defined in a gate electrode each connected to a pad as illustrated in FIGS. 12 and 13, fine-line interconnection resistance in the gate electrode can be evaluated by measuring the amount of voltage drop in the gate electrode, for example.

Further characteristically, when the plurality of gate electrodes are all of the same shape and the plurality of gate electrodes have their respective ends defined in a gate width direction each connected to a pad as in FIG. 13, voltage drop in each gate electrode is measured to evaluate resistance matching in gate electrode. The resistance matching referred to here is directed to determine to what extent resistors designed to have the same size are equal in performance.

<Other Embodiments>

A method of automatically arranging transistors for forming TEG in in-line TEG's in a wafer has been described in the first and second preferred embodiments in reference to FIGS. 2 and 3 that is to be employed in designing layout of the wafer using a computer.

Similar to the first and second preferred embodiments, a method of automatically arranging transistors for forming TEG in the in-line TEG's in a wafer to be employed in designing layout of the wafer using a computer is also applicable to the semiconductor device according to the fourth, fifth and sixth preferred embodiments. In the fourth, fifth and sixth preferred embodiments, the constituent elements of the in-line TEG's in each preferred embodiment may be automatically arranged by a computer in such a way that these elements satisfy their respective conditions required in each preferred embodiment.

The arrangement according to this way realizes a method of arranging transistors for forming TEG in the in-line TEG's that facilitates formation of in-line TEG's in each preferred embodiment.

While the invention has been shown and described in detail, the foregoing description is in all aspects illustrative and not restrictive. It is therefore understood that numerous modifications and variations can be devised without departing from the of the invention.

What is claimed is:

1. A semiconductor device, comprising:
a pad; and
a plurality of transistors arranged in a line for forming TEG, each of said plurality of transistors having a first current electrode, a second current electrode and a control electrode,
wherein respective first current electrodes of said plurality of transistors are commonly connected to said pad by an interconnect line, and
said plurality of transistors are arranged from closer part to said pad in descending order of current-driving capability.

2. The semiconductor device according to claim 1,
wherein said plurality of transistors are MOS transistors each having a source electrode, a drain electrode and a gate electrode respectively corresponding to said first current electrode, said second current electrode and said control electrode, and
said plurality of transistors are arranged from said closer part in descending order of value obtained by dividing a gate width of said gate electrode by a gate length thereof.

3. A method of arranging transistors for forming TEG in a layout design, said transistors being a plurality of transistors arranged in a line each having a first current electrode, a second current electrode and a control electrode, comprising the steps of:
(a) determining specifications of said plurality of transistors to be arranged in said TEG;
(b) comparing said plurality of transistors in level of current-driving capability; and
(c) arranging said plurality of transistors in descending order of current-driving capability from closer part to said pad to which respective first current electrodes of said plurality of transistors are commonly connected by an interconnect line.

4. The method according to claim 3,
wherein said plurality of transistors are MOS transistors each having a source electrode, a drain electrode and a gate electrode respectively corresponding to said first current electrode, said second current electrode and said control electrode, and
in said step (c), said plurality of transistors are arranged from said closer part in descending order of value obtained by dividing a gate width of said gate electrode by a gate length thereof.

5. A semiconductor device, comprising:
a pad; and
a plurality of transistors for forming TEG, each of said plurality of transistors having a first current electrode, a second current electrode and a control electrode,
wherein respective first current electrodes of said plurality of transistors are commonly connected to said pad by an interconnect line, and
each of said plurality of transistors satisfies following equation,
$$N R ≦ \frac{r}{R S H \cdot S g}$$
where NR is the number of sheets in said interconnect line, RSH is sheet resistance in said interconnect line, Sg is conductance obtained by differentiating a current value between first and second current electrodes with respect to a voltage value between control electrode and first current electrode, and r is a value obtained by dividing the amount of reduction in current resulting from resistance in said interconnect line by a current value between first and second current electrodes.

6. A method of arranging transistors for forming TEG in a layout design, said transistors being a plurality of transistors each having a first current electrode, a second current electrode and a control electrode,
wherein respective first current electrodes of said plurality of transistors are commonly connected to a pad,
said method comprising the steps of:
(a) determining specifications of said plurality of transistors to be arranged in said TEG;
(b) determining whether each of said plurality of transistors satisfies following equation:
$$N R ≦ \frac{r}{R S H \cdot S g}$$
where NR is the number of sheets in said interconnect line, RSH is sheet resistance in said interconnect line, Sg is conductance obtained by differentiating a current value between first and second current electrodes with respect to a voltage value between control electrode and first current electrode, and r is a value obtained by dividing the amount of reduction in current resulting from resistance in said interconnect line by a current value between first and second current electrodes; and
(c) removing a transistor that is determined to achieve no satisfaction of said equation in said step (b) and arranging a remaining transistor.

7. A semiconductor device, comprising:
a plurality of pads; and
a plurality of transistors for forming TEG arranged to be in line with said plurality of pads, each of said plurality of transistors having a first current electrode, a second current electrode and a control electrode,
wherein respective first current electrodes of said plurality of transistors are commonly connected to one of said plurality of pads by an interconnect line,
respective second current electrodes of said plurality of transistors are independently connected to remaining ones of said plurality of pads separate from each other, and
said interconnect line is placed above or below said pads having connection to said second current electrodes without contact therebetween.

8. A semiconductor device, comprising:
a pad; and
at least two transistors for forming TEG arranged to be in line with said pad, each of said at least two transistors having a first current electrode, a second current electrode and a control electrode,
wherein said pad is arranged between said at least two transistors, and
said pad is connected to respective first current electrodes of said at least two transistors arranged on both sides thereof by respective interconnect lines.

9. A semiconductor device, comprising:
at least two pads; and
one or a plurality of transistors for forming TEG, each of said one or said plurality of transistors having a first current electrode, a second current electrode and a control electrode,
wherein said one or said plurality of transistors are arranged between said at least two pads to be in line with said at least two pads, and
said one or said plurality of transistors are arranged axially symmetrically about a centerline as an axis of symmetry defined between said at least two pads.

10. A semiconductor device, comprising:
a plurality of gate electrodes arranged in parallel; and
an active region cutting across said plurality of gate electrodes,
wherein source regions and drain regions are alternately provided to said active region between said plurality of gate electrodes.

11. The semiconductor device according to claim 10, further comprising:
a source interconnect line placed to be perpendicular to said plurality of gate electrodes, said source interconnect line establishing connection between said source regions; and
a drain interconnect line placed to be perpendicular to said plurality of gate electrodes, said drain interconnect line establishing connection between said drain regions.

12. The semiconductor according to claim 10,
wherein said plurality of gate electrodes are classified into at least two types, each of said at least two types having connection to a pad.

13. The semiconductor device according to claim 10,
wherein at least one of said plurality of gate electrodes has ends defined in a gate width direction each connected to a pad.

14. A semiconductor device, comprising:
a gate electrode; and
a plurality of active regions arranged in parallel, each of said plurality of active regions cutting across said gate electrode.

15. The semiconductor device according to claim 14,
wherein said gate electrode has ends defined in a gate width direction each connected to a pad.

16. The semiconductor device according to claim 14,
wherein at least one of said plurality of active regions serves as a dummy active region not to be used as a device.
